(19) United States
(12) Patent Application Publication
(10) Pub. No.: US 2008/0057410 A1
(43) Pub. Date: Mar. 6, 2008

(54) Method of repairing a photolithographic mask

(76) Inventors: Wen-Hao Cheng, Fremont, CA (US); Jeffrey N. Farnsworth, Los Gatos, CA (US); Rajesh Nagpal, Los Altos, CA (US); Eric A. Frendberg, Dublin, CA (US); Wai Yip Kwok, Santa Cruz, CA (US)

Correspondence Address: Stephen M. De Klerk;BLAKELY, SOKOLOFF, TAYLOR & ZAFMAN LLP, Seventh Floor, 12400 Wilshire Boulevard, Los Angeles, CA, 90025, US

(21) Appl. No.: 11/515,049

(22) Filed: Aug. 31, 2006

(51) Int. Cl. G03C 5/00; G03F 1/00

(52) U.S. Cl. 430/5; 430/322; 430/30; 430/394

(57) ABSTRACT

A method is described for repairing a defect detected in a photolithographic mask. A phase voxel cavity is formed in the photolithographic mask to compensate for the defect in the photolithographic mask. The phase voxel cavity and features of the mask both create a phase shift of approximately π.

### BACKGROUND OF THE INVENTION

1). Field of the Invention

Embodiments of this invention relate to a method of repairing a defect in a photolithographic mask, a method of forming an electronic substrate and to a photolithographic mask.

2). Discussion of Related Art

Microelectronic circuits are usually formed in and on silicon or other semiconductor wafers. Such a circuit has many layers formed on top of one another in a z-direction. Each layer also has features in an x-y plane. A metal line may, for example, extend in an x-direction followed by a y-direction and then again in an x-direction.

Photolithographic techniques are utilized to form such features. A photoresist material is deposited on a substrate, and is then exposed to light having a pre-selected wavelength. A mask is located between a light source and the photoresist material and the mask carries a pattern with certain areas either attenuating or allowing full transmission of the light. Optics focus and reduce the size of an image from the mask and the pattern of the mask is transmitted or reflected on the photoresist material. Selective exposure of the photoresist material causes selective changing in the composition of the photoresist material. A selective etchant has been used to remove portions of the photoresist material. The pattern created in the photoresist material can then be used for further processing. Metal lines may, for example, be formed within removed areas of the photoresist material.

A defect is sometimes formed during the fabrication of a mask. Such a defect will result in a corresponding defect in a circuit that is formed in and on the substrate. The same mask is typically used for printing many of the same circuit. Each circuit will have the same defect. Mask repair is usually accomplished by replacing a portion of the mask that is inadvertently removed with the same type of material. Rebuilding of a defective portion of a mask is expensive, intricate and inherently inaccurate.

### BRIEF DESCRIPTION OF THE DRAWINGS

Embodiments of the invention are described by way of examples with reference to the accompanying drawings, wherein:

FIG. 1 is a side view representing an apparatus for photolithographically defining features on photoresist material for purposes of forming an electronics component;

FIG. 2 is a perspective view illustrating a photolithographic mask that can be used in the apparatus of FIG. 1;

FIG. 3 is a perspective view of a photolithographic mask that is similar to the photolithographic mask of FIG. 2, but has a defect due to mesa lifting;

FIG. 4 is a view similar to FIG. 3 wherein the defect is compensated for by forming a phase voxel cavity;

FIG. 5 is a top-down view illustrating at different defocus lengths the critical dimension of a line that is formed utilizing the photolithographic mask of FIG. 2;

FIG. 6 is a view similar to FIG. 5 wherein the photolithographic mask of FIG. 3 is used;

FIG. 7 is a view similar to FIG. 6 wherein the photolithographic mask of FIG. 4 is used;

FIG. 8 is a graph wherein the critical dimensions of FIGS. 5, 6, and 7 are plotted for a required critical dimension of 80 nm and at different defocus lengths;

FIG. 9 is a flowchart of how an electronics component is fabricated;

FIG. 10 is a perspective view of a photolithographic mask that can alternatively be used in the apparatus of FIG. 1, wherein the mask has an end-to-end structure;

FIG. 11 is a perspective view of a photolithographic mask that is similar to the photolithographic mask of FIG. 10, except that a critical width between two structures of the end-to-end structure is too large and the mask is therefore defective;

FIG. 12 is a view similar to FIG. 11 wherein the defect is compensated for by forming a phase voxel cavity;

FIG. 13 is a graph wherein the critical dimensions at various defocus lengths are plotted when using the photolithographic masks of FIGS. 10, 11, and 12 respectively;

FIG. 14 is a bottom view of a photolithographic mask that can be used as a further alternative in the apparatus of FIG. 1, the mask being of an alternating phase shift type with a chromium layer to attenuate light;

FIG. 15 is a bottom view of a photolithographic mask and is similar to the mask of FIG. 14 except that a portion of the chromium layer is inadvertently removed to leave an area of an underlying transparent substrate exposed; and

FIG. 16 is a figure similar to FIG. 15, wherein the area is compensated for by forming two phase voxel cavities within the area.

### DETAILED DESCRIPTION OF THE INVENTION

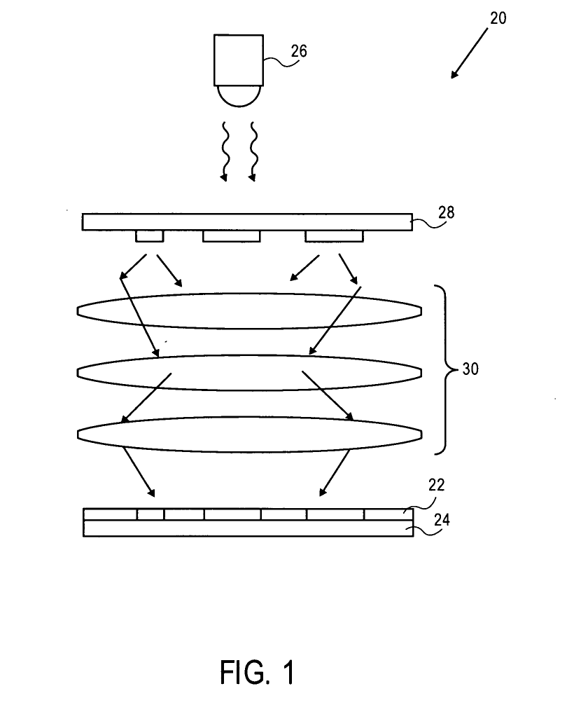

FIG. 1 of the accompanying drawings illustrates apparatus 20 that is used for photolithographically defining features on photoresist material 22 deposited on an electronics substrate 24

The apparatus 20 includes a light source 26, a photolithographic mask 28, and an optical system of lenses 30. The light source 26 emanates light having a wavelength of approximately 193 nm. The photolithographic mask 28 is placed in a path of the light from the light source 26 so that the light propagates through the photolithographic mask 28 in a z-direction. The lenses 30 are placed in a path of the light after it passes through the photolithographic mask 28. The light radiates onto the photoresist material 22 after passing through the lenses 30.

The photolithographic mask 28 is made of a transparent material and carries a two-dimensional pattern of features in x-and-y directions. The features of the photolithographic mask 28 may attenuate the light or may change its phase to thereby reduce the brightness of the light either partially or entirely, depending on the type of mask that is used. The features of the photolithographic mask 28 result in features being created by the light radiating on the photoresist material 22. The pattern of the features of the photolithographic mask 28 may or may not be exactly replicated on the photoresist material 22, but the lenses 30 generally create a reduction in the overall size of the pattern, so that the pattern created on the photoresist material 22 has a cross-dimension that is approximately one-quarter of the pattern on the photolithographic mask 28.

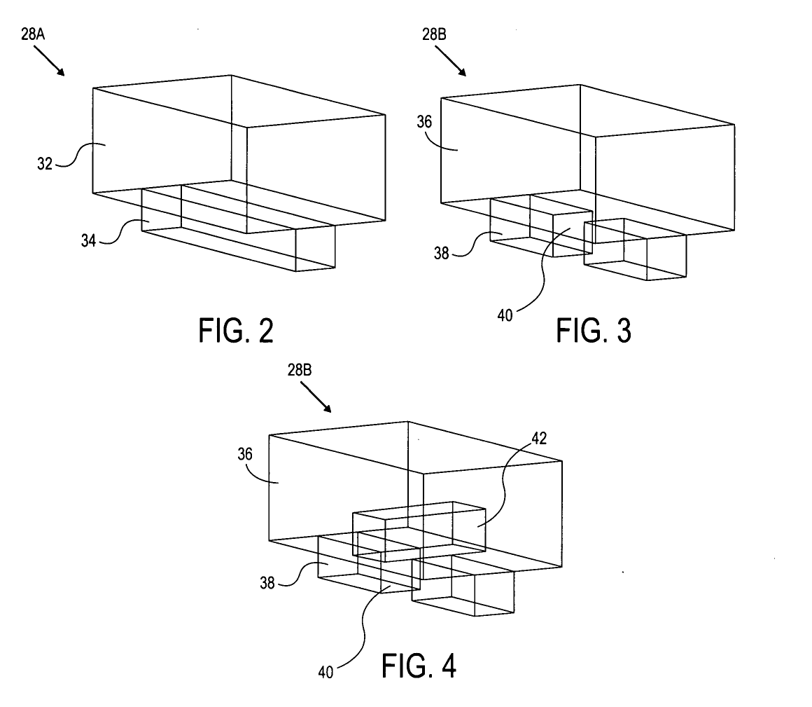

FIG. 2 illustrates one type of photolithographic mask 28A that may be used in the system of FIG. 1. The photolithographic mask 28A includes a transparent glass substrate 32 with a mesa pattern 34 on a lower surface of the transparent glass substrate 32. The mesa pattern 34 is formed on select areas only of the lower surface of the transparent glass substrate 32. Light passing through areas of the photolithographic mask 28A where the mesa pattern 34 is located leaves the mesa pattern 34 with a reference phase of 0 degrees. Light leaving the photolithographic mask 28A where the mesa pattern 34 is absent has a phase that is out-of-phase with respect to light leaving the mesa pattern 34 by π. The thickness of the mesa pattern is given by the following formula:

$$Z = \frac{λ}{2 ( n - 1 )} , wherein$$

Z is the thickness of the mesa pattern;

n is the refractive index of glass, namely 1.56;

λ is the wavelength of the light, in this case 193 nm;

The thickness of the mesa pattern 34 is thus 172 nm.

FIG. 3 illustrates a photolithographic mask 28B that is the same as the photolithographic mask 28A of FIG. 2 in the sense that it includes a transparent substrate 36 and a mesa pattern 38 similar to the transparent glass substrate 32 and mesa pattern 34 of the photolithographic mask 28A of FIG. 2. The mesa pattern 38, however, includes a defect 40 where the mesa pattern 38 is absent. Light leaving the photolithographic mask 28B where the defect 40 is located has a phase of π and should have a phase of 0 degrees. Referring again to FIG. 1, the defect 40 in FIG. 3 will cause a corresponding defect in the pattern created in the photoresist material 22.

FIG. 4 illustrates how the defect is compensated for. A phase voxel cavity 42 is etched into the transparent substrate 36 in an area of the defect 40. The phase voxel cavity 42 is etched to a depth of 170 nm. A relatively precise etching depth can be obtained because the etching rate would be known and the required depth of 170 nm is the etching rate multiplied by time. Light leaving the transparent glass substrate 36 in the area of the phase voxel cavity 42 will have a phase of 0 degrees. The light thus has the same phase as if the mesa pattern 38 did not have the defect 40, because they are out-of-phase by 2π, as is the case with the mesa pattern 34 in FIG. 2.

A degree of computer simulation may be required to determine the required width for the phase voxel cavity 42 because the phase voxel cavity 42 may not have a footprint that matches the footprint of the defect 40 exactly. In the present example, the defect 40 is 183 nm wide and 200 nm long and the phase voxel cavity 42 is 344 nm wide and 200 nm long.

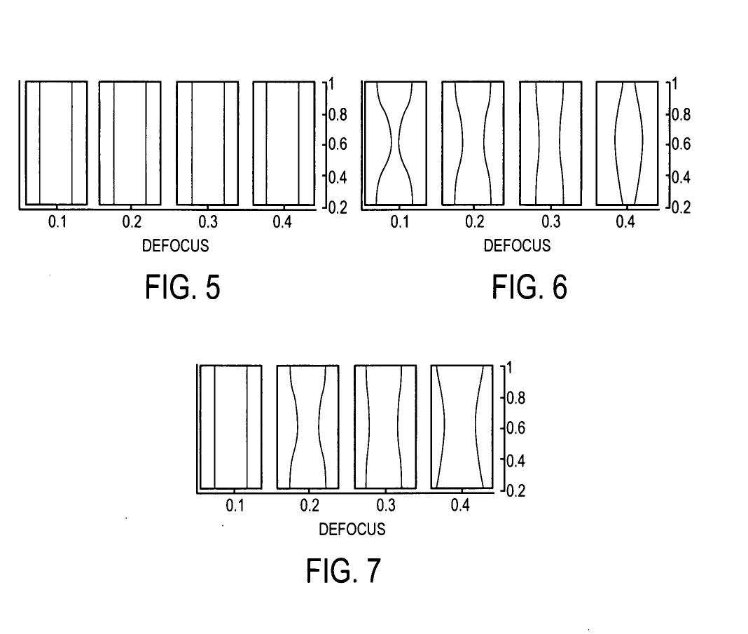

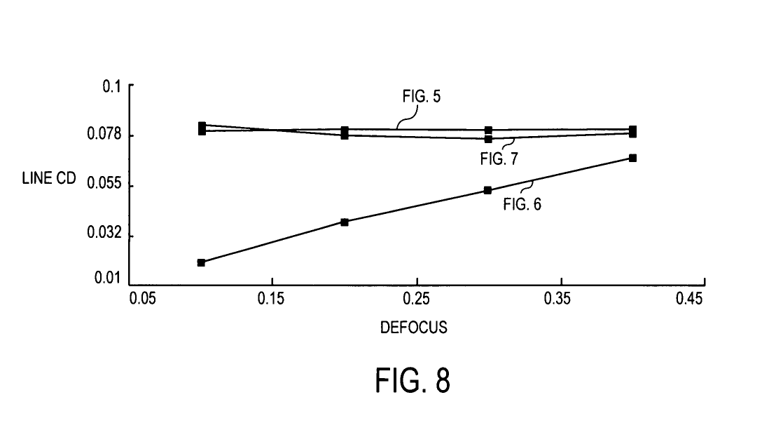

FIG. 5 illustrates a critical dimension of a pattern that is formed on a photoresist material using the photolithographic mask 28A of FIG. 2. FIG. 6 illustrates a pattern that is created using the photolithographic mask 28B of FIG. 3, and FIG. 7 illustrates a pattern that is created using the photolithographic mask 28B of FIG. 4. The defect in the pattern can be seen when comparing FIG. 6 with FIG. 5. Partial reparation of the pattern is created with the phase voxel cavity 42 in FIG. 4, as is shown in FIG. 7. FIG. 8 illustrates the actual dimension for a critical dimension of 80 nm at different defocus distances and including FIGS. 5, 6, and 7.

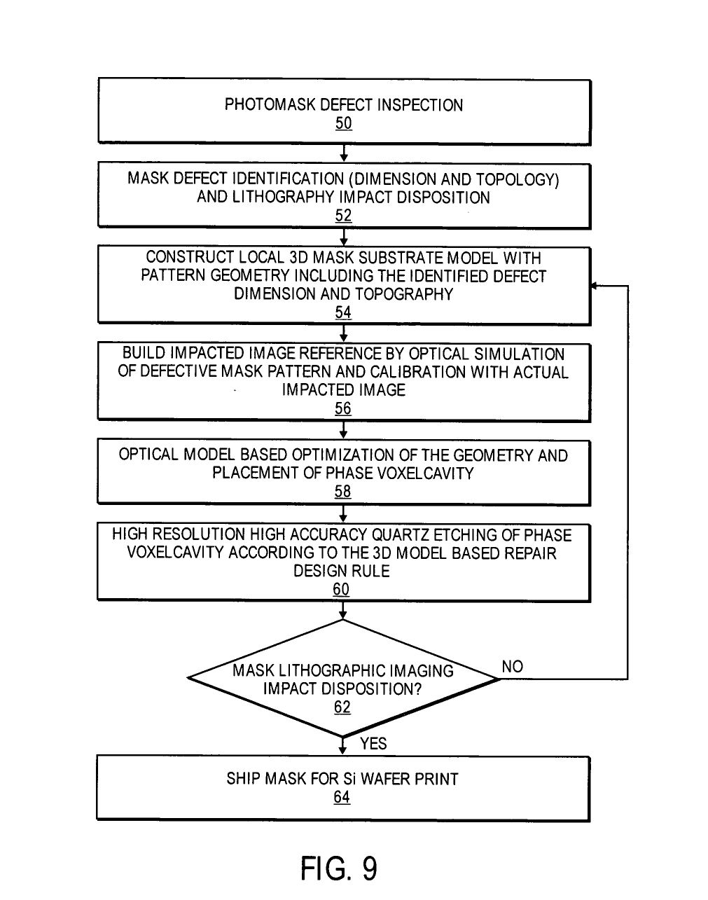

FIG. 9 illustrates a method of forming an electronics component, including the electronics substrate 24 of FIG. 1. At Block 50 a photo mask defect inspection is carried out. Defect inspection is typically accomplished by scanning the mask. Block 52 is for mask defect identification (including dimension and topography) and lithography impact deposition. Defects are typically identified by comparing adjacent areas of the mask for inconsistencies.

Next, at Block 54, a local three-dimensional mask substrate model is constructed on a computer. The model has pattern geometry including the identified defect dimension and topography.

At Block 56 an impacted image reference is built. The impacted reference image is built by optical simulation of the defective mask pattern and is calibrated with the actual impacted image.

At Block 58 an optical model is created based on optimization of the three-dimensional geometry and placement of a phase voxel cavity. The optical model is created for purposes of determining a mask repair design rule.

At Block 60 a high-resolution, high-accuracy quartz etching of a phase voxel cavity is carried out according to the three-dimensional model-based repair design rule.

At Block 62 a mask lithographic imaging impact deposition is carried out.

The process of steps 54, 56, 58, 60, and 62 are carried out until the deposition specification is passed. At Block 64, the mask is shipped for silicon wafer printing.

In one embodiment, a method of repairing a defect detected in the photolithographic mask is described, including forming a phase voxel cavity in the photolithographic mask to compensate for the defect in the photolithographic mask.

The phase voxel cavity may be approximately 172 nm deep, although it will be appreciated that the phase voxel cavity may have any depth, provided that the depth is selected to create the necessary cancellation of light having a predetermined and select wavelength.

In the embodiment described above, the photolithographic mask is a phase mask with a mesa pattern creating a π phase change, the mesa pattern having a defect, and the phase voxel cavity having a depth creating an additional π phase change.

In one embodiment, a method of forming an electronics component is described, including (i) manufacturing a photolithographic mask having a transparent substrate and mask features carried by the transparent substrate, the mask features having a defect, (ii) detecting the defect, (iii) forming a phase voxel cavity in the photolithographic mask, and (iv) directing light through the mask onto the substrate, the mask features causing substrate features on the substrate and the phase voxel cavity compensating for a defect in at least one of the substrate features should the phase voxel cavity be absent.

With specific reference to FIG. 9, the method may include (i) constructing a model including the defects, (ii) building an impacted image reference by optical simulation of a photolithographic mask having the defect and calibrating with an impacted image, and (iii) forming a phase voxel cavity into the model to compensate for the defect.

The light has a wavelength of approximately 193 nm, in which case the phase voxel cavity is approximately 172 nm deep. Other wavelengths of light and phase voxel cavities may apply in other embodiments.

A photolithographic mask is also described. The photolithographic mask includes a transparent substrate, features carried by the transparent substrate such that a pattern-generating phase shift occurs between light of a pre-selected wavelength propagating through the transparent substrate where the features are compared to where the features are absent, the pattern-generating phase shift being approximately π; and a phase voxel cavity formed in the transparent substrate to create a correcting phase shift of 2π between light propagating through the features and light propagating through the phase voxel cavity. The photolithographic mask in the embodiment described above is a phase mask with a mesa pattern creating a π phase change, the mesa pattern having a defect, and the phase voxel cavity having a depth creating an additional π phase change.

The masks 28A can be used for photolithography or optical lithography. Photolithography or optical lithography is a process used in semiconductor device fabrication to transfer a pattern from a photomask (also called reticle) to the surface of a substrate. Often crystalline silicon in the form of a wafer is used as a choice of substrate, although there are several other options including, but not limited to, glass, sapphire, and metal. Photolithography (also referred to as “microlithography” or “nanolithography”) bears a similarity to the conventional lithography used in printing and shares some of the fundamental principles of photographic processes.

Photolithography involves a combination of: (i) substrate preparation, (ii) photoresist application, (iii) soft-baking, (iv) exposure, (v) developing, (vi) hard-baking, and (vii) etching, and various other chemical treatments (thinning agents, edge-bead removal, etc.) in repeated steps on an initially flat substrate.

A part of a typical silicon lithography procedure would begin by depositing a layer of conductive metal several nanometers thick on the substrate. A layer of photoresist—a chemical that hardens when exposed to light (often ultraviolet)—is applied on top of the metal layer. The photoresist is selectively “hardened” by illuminating it in specific places. For this purpose a transparent plate with patterns printed on it, called a photomask or shadowmask, is used together with an illumination source to shine light on specific parts of the photoresist. Some photoresists work well under broadband ultraviolet light, whereas others are designed to be sensitive at specific frequencies to ultraviolet light. It is also possible to use other types of resist that are sensitive to x-rays and others that are sensitive to electron-beam exposure.

A spinner is used to apply photoresist to the surface of a silicon wafer.

Generally most types of photoresist will be available as either “positive” or “negative.” With positive resists, the area that you can see (masked) on the photomask is the area that you will see upon developing of the photoresist. With negative resists it is the inverse, so any area that is exposed will remain, whilst any areas that are not exposed will be developed. After developing, the resist is usually hard-baked before being subjected to a chemical etching stage which will remove the metal underneath.

Finally, the hardened photoresist is etched using a different chemical treatment, and all that remains is a layer of metal in the same shape as the mask (or the inverse if negative resist has been used).

Lithography is used because it affords exact control over the shape and size of the objects it creates, and because it can create patterns over an entire surface simultaneously. Its main disadvantages are that it requires a substrate to start with, it is not very effective at creating shapes that are not flat, and it can require extremely clean operating conditions.

In a complex integrated circuit (for example, CMOS), a wafer will go through the photolithographic area up to 50 times. For Thin-Film-Transistor (TFT) processing, many fewer photolithographical processes are usually required.

A wafer is introduced onto an automated “wafertrack” system. This track consists of handling robots, bake/cool plates, and coat/develop units. The robots are used to transfer wafers from one module to another. The wafer is initially heated to a temperature sufficient to drive off any moisture that may be present on the wafer surface. Hexa-methyl-disilizane (HMDS) is applied in either liquid or vapor form in order to promote better adhesion of the photosensitive polymeric material, called photoresist. Photoresist is dispensed in a liquid form onto the wafer as it undergoes rotation. The speed and acceleration of this rotation are important parameters in determining the resulting thickness of the applied photoresist. The photoresist-coated wafer is then transferred to a hot plate, where a “soft bake” is applied to drive off excess solvent before the wafer is introduced into the exposure system.

The simplest exposure system is a contact printer or proximity printer. A contact printer involves putting a photomask in direct contact with the wafer. A proximity printer puts a small gap in between the photomask and wafer. The photomask pattern is directly imaged onto the photoresist on the wafer in both cases. The resolution is roughly given by the square root of the product of the wavelength and the gap distance. Hence, contact printing with zero gap distance ideally offers best resolution. Defect considerations have prevented its widespread use today. However, the resurgence of nanoimprint lithography may revive interest in this familiar technique, especially since the cost of ownership is expected to be very low. The cost will be low due to the lack of a need for complex optics, expensive light sources, or specially tailored resists.

The commonly used approach for photolithography today is projection lithography. The desired pattern is projected from the photomask onto the wafer in either a machine called a stepper or scanner. The stepper/scanner functions similarly to a slide projector. Light from a mercury arc lamp or excimer laser is focused through a complex system of lenses onto a “mask” (also called a reticle), containing the desired image. The light passes through the mask and is then focused to produce the desired image on the wafer through a reduction lens system. The reduction of the system can vary depending on design, but is typically on the order of 4×-5× in magnitude.

When the image is projected onto the wafer, the photoresist material undergoes some wavelength-specific radiation-sensitive chemical reactions, which cause the regions exposed to light to be either more or less acidic. If the exposed regions become more acidic, the material is called a positive photoresist, while if it becomes less susceptible it is a negative photoresist. The resist is then “developed” by exposing it to an alkaline solution that removes either the exposed (positive photoresist) or the unexposed (negative photoresist) region. This process takes place after the wafer is transferred from the exposure system back to the wafertrack.

Developers originally often contained sodium hydroxide (NaOH). However, sodium is considered an extremely undesirable contaminant in MOSFET fabrication because it degrades the insulating properties of gate oxides. Metal-ion-free developers such as tetramethyl ammonium hydroxide (TMAH) are now used.

A post-exposure bake is performed before developing, typically to help reduce standing wave phenomena caused by the destructive and constructive interference patterns of the incident light. The developing chemistry is delivered in a similar fashion to how the photoresist was applied. The resulting wafer is then “hardbaked” on a bake plate at high temperature in order to solidify the remaining photoresist, to better serve as a protecting layer in future ion implantation, wet chemical etching, or plasma etching.

The ability to project a clear image of a very small feature onto the wafer is limited by the wavelength of the light that is used and the ability of the reduction lens system to capture enough diffraction orders from the illuminated mask. Current state-of-the-art photolithography tools use deep ultraviolet (DUV) light with wavelengths of 248 nm and 193 nm, which allow minimum resist feature sizes down to 50 nm.

Optical lithography can be extended to feature sizes below 50 nm using 193 nm and liquid immersion techniques. Also termed immersion lithography, this enables the use of optics with numerical apertures exceeding 1.0. The liquid used is typically ultra-pure, deionised water, which provides for a refractive index above that of the usual air gap between the lens and the wafer surface. This is continually circulated to eliminate thermally-induced distortions. Using water will only allow numerical apertures of up to ˜1.4 but higher refractive index materials will allow the effective numerical aperture to be increased.

Tools using 157 nm wavelength DUV in a manner similar to current exposure systems have been developed. These were once targeted to succeed 193 nm at the 65 nm feature size node but have now all but been eliminated by the introduction of immersion lithography. This was due to persistent technical problems with the 157 nm technology and economic considerations that provided strong incentives for the continued use of 193 nm technology. High-index immersion lithography is the newest extension of 193 nm lithography to be considered. In 2006, features less than 30 nm have been demonstrated by IBM using this technique. Other alternatives are extreme ultraviolet lithography (EUV), nanoimprint lithography, and contact printing. EUV lithography systems are currently under development which will use 13.5 nm wavelengths, approaching the regime of x-rays. Nanoimprint lithography is being investigated by several groups as a low-cost, non-optical alternative. Contact printing has already been established years ago and may yet be revived with the recent strong interest in nanoimprint lithography.

The image for the mask is originated from a computerized data file. This data file is converted to a series of polygons and written onto a square fused quartz substrate covered with a layer of chrome using a photolithographic process. A beam of electrons is used to expose the pattern defined in the data file and travels over the surface of the substrate in either a vector or raster scan manner. Where the photoresist on the mask is exposed, the chrome can be etched away, leaving a clear path for the light in the stepper/scanner systems to travel through.

Optical lithography can be extended to a resolution of 15 nm by using the short wavelengths of 1 nm x-ray lithography for the illumination. This is implemented by the proximity printing approach. The technique is developed to the extent of batch processing. The extension of the method relies on Near Field x-rays in Fresnel diffraction: a clear mask feature is “demagnified” by proximity to a wafer that is set near to a “Critical Condition.” This condition determines the mask-to-wafer gap and depends on both the size of the clear mask feature and on the wavelength. The method is rapid because it uses broadband, and simple because it requires no lenses.

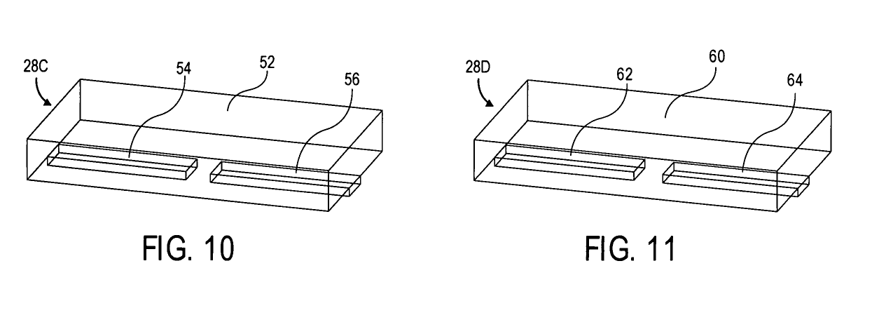

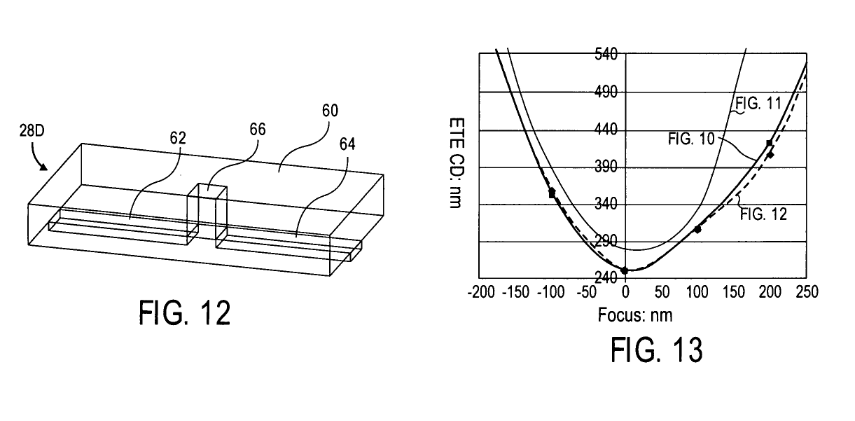

FIG. 10 illustrates a photolithographic mask 28C that is non-defective. Photolithographic mask 28C has a transparent substrate 52 with two structures 54 and 56 made out of MoSi forming features of the photolithographic mask 28C. The structures 54 and 56 have an end-to-end critical dimension of 96 nm, for purposes of forming a structure on a substrate having a dimension of 24 nm.

FIG. 11 illustrates a photolithographic mask 28D that is similar to the photolithographic mask 28C of FIG. 10, in the sense that the photolithographic mask 28D has a transparent substrate 60 and two structures 62 and 64 formed on the transparent substrate 60. The photolithographic mask 28D differs from the photolithographic mask 28C in that the structures 62 and 64 have an end-to-end width of 112 nm, which would result in a structure on a substrate having a width of 28 nm. The structures 62 and 64 are thus defective in that they are 60 nm too wide or far apart.

FIG. 12 illustrates one method of correcting or compensating for the oversized end-to-end relationship between the structures 62 and 64. In the embodiment of FIG. 12, a phase voxel cavity 66 is etched in the transparent substrate 60 in an area between the structures 62 and 64. The phase voxel cavity 66 has a width of approximately 28 nm, a length of approximately 4 nm, and a depth of approximately 170 nm. A footprint of the phase voxel cavity 66 is thus smaller than a footprint of an area between the structures 62 and 64, so that the phase voxel cavity 66 does not entirely eliminate light passing through the area between the structures 62 and 64 and only reduces the overall intensity of the light.

As can be seen in FIG. 13, the photolithographic mask 28D of FIG. 12 has approximately the same critical dimension at all the focus lengths as the photolithographic mask 28C of FIG. 11, even though the photolithographic mask 28D of FIG. 10 results in a different critical dimension at all the focus lengths.

In the embodiment above the photolithographic mask has two structures with an end-to-end critical dimension that is too large, the phase voxel cavity being formed between the two structures.

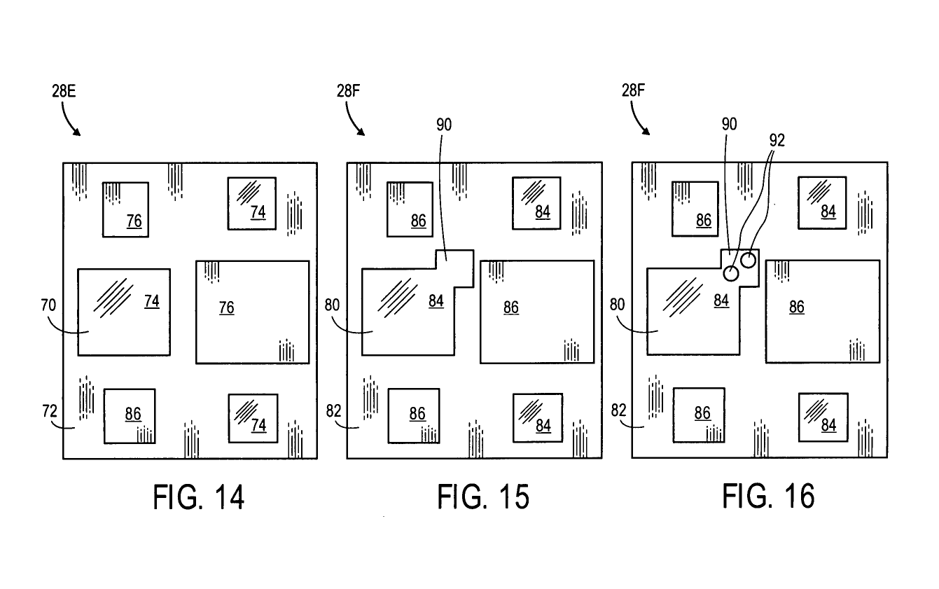

FIG. 14 illustrates another photolithographic mask 28E of the alternating phase-shift type. The photolithographic mask 28E includes a transparent substrate 70 with a chromium layer 72 formed on the transparent substrate 70. The chromium layer 72 is etched to leave windows 74 and 76 of the transparent substrate 70 visible. The transparent substrate 70 is also further etched in the areas of the windows 76 so that the transparent substrate 70 is deeper where the windows 76 are than where the windows 74 are. The windows 74 represent light at 0 degrees and the windows 76 light at π. The chromium layer 72 is opaque and attenuates all light.

FIG. 15 illustrates a photolithographic mask 28F which is the same as the photolithographic mask 28E of FIG. 14, in the sense that it has a transparent substrate 80 and a chromium layer 82 that defines windows 84 and 86, with the windows 86 being etched deeper than the windows 84. In addition, the photolithographic mask 28F has a defect because a portion of the chromium layer 82 is inadvertently removed to leave an area 90 of the transparent substrate 80 exposed.

In FIG. 16 the defect due to the area 90 in FIG. 15 is compensated for by etching two phase voxel cavities 92 into the transparent substrate 80 within the area 90. The phase voxel cavities 92 are smaller than the area 90 and partially cancel light from the square area 90.

In the given embodiment, light having a wavelength of 193 nm is used. With a refractive index of 1.56 for glass, the windows 76, 86, and the phase voxel cavities 92 would have to be etched to a depth of 172 nm below the surface of the windows 74 and 84. However, due to an effective phase of the light, the areas within the windows 76 and 86 and the phase voxel cavities 92 are etched to a depth of 160 nm below the surface of the windows 74 and 84. The effective phase is a function of geometry, illumination, etc.

In the embodiment above, the photolithographic mask has a transparent substrate and a nontransparent layer formed on the transparent substrate, the defect being the absence of a portion of the nontransparent layer to leave an area of the transparent substrate exposed, the phase voxel cavity being formed in the area.

While certain exemplary embodiments have been described and shown in the accompanying drawings, it is to be understood that such embodiments are merely illustrative and not restrictive of the current invention, and that this invention is not restricted to the specific constructions and arrangements shown and described since modifications may occur to those ordinarily skilled in the art.

What is claimed:

1. A method of repairing a defect detected in photolithographic mask, comprising:
forming a phase voxel cavity in the photolithographic mask to compensate for the defect in the photolithographic mask.

2. The method of claim 1, wherein the phase voxel cavity is approximately 172 nm deep.

3. The method of claim 1, wherein the photolithographic mask is a phase mask with a mesa pattern creating a π phase change, the mesa pattern having a defect, and the phase voxel cavity having a depth creating an additional π phase change.

4. The method of claim 1, wherein the photolithographic mask has two structures with an end-to-end critical dimension that is too large, the phase voxel cavity being formed between the two structures.

5. The method of claim 1, wherein the photolithographic mask has a transparent substrate and a nontransparent layer formed on the transparent substrate, the defect being the absence of a portion of the nontransparent layer to leave an area of the transparent substrate exposed, the phase voxel cavity being formed in the area.

6. A method of forming an electronics component, comprising:
manufacturing a photolithographic mask having a transparent substrate and mask features carried by the transparent substrate, the mask features having a defect;
detecting the defect;
forming a phase voxel cavity in the photolithographic mask; and
directing light through the mask onto the substrate, the mask features causing substrate features on the substrate and the phase voxel cavity compensating for a defect in at least one of the substrate features should the phase voxel cavity be absent.

7. The method of claim 6, further comprising;
constructing a model including the defects;
building an impacted image reference by optical simulation of a photolithographic mask having the defect and calibrating with an impacted image; and
forming a phase voxel cavity into the model to compensate for the defect.

8. The method of claim 6, wherein the light has a wavelength of approximately 193 nm.

9. The method of claim 8, wherein the phase voxel cavity is approximately 172 nm deep.

10. The method of claim 6, wherein the photolithographic mask is a phase mask with a mesa pattern creating a π phase change, the mesa pattern having a defect, and the phase voxel cavity having a depth creating an additional π phase change.

11. The method of claim 6, wherein the photolithographic mask has two structures with an end-to-end critical dimension that is too large, the phase voxel cavity being formed between the two structures, to correct the critical dimension error.

12. The method of claim 6, wherein the photolithographic mask has a transparent substrate and a nontransparent layer formed on the transparent substrate, the defect being the absence of a portion of the nontransparent layer to leave an area of the transparent substrate exposed, the phase voxel cavity being formed in the area, to correct the defective and exposed transparent substrate error.

13. A photolithographic mask comprising:
a transparent substrate;
features carried by the transparent substrate such that a pattern-generating phase shift occurs between light of a pre-selected wavelength propagating through the transparent substrate where the features are compared to where the features are absent, the pattern-generating phase shift being approximately π; and
a phase voxel cavity formed in the transparent substrate to create a correcting phase shift of 2π between light propagating through the features and light propagating through the phase voxel cavity.

14. The photolithographic mask of claim 13, wherein the photolithographic mask is a phase mask with a mesa pattern creating a π phase change, the mesa pattern having a defect, and the phase voxel cavity having a depth creating an additional π phase change.

15. The photolithographic mask of claim 13, wherein the photolithographic mask has two structures with an end-to-end critical dimension that is too large, the phase voxel cavity being formed between the two structures, to correct the critical dimension error.

16. The photolithographic mask of claim 13, wherein the photolithographic mask has a transparent substrate and a nontransparent layer formed on the transparent substrate, the defect being the absence of a portion of the nontransparent layer to leave an area of the transparent substrate exposed, the phase voxel cavity being formed in the area, to correct the defective and exposed transparent substrate error.
